(19) United States
(12) Patent Application Publication
(10) Pub. No.: US 2012/0024366 A1
(43) Pub. Date: Feb. 2, 2012

(54) Thin film solar cell structure and fabricating method thereof

(75) Inventors: Chee Wee Liu, Taipei (TW); Wen Wei Hsu, Taipei (TW); Tzu Huan Cheng, Taipei (TW); Wei Shuo Ho, Taipei (TW)

(73) Assignee: NATIONAL TAIWAN UNIVERSITY, Taipei (TW)

(21) Appl. No.: 12/926,089

(22) Filed: Oct. 26, 2010

(30) Foreign Application Priority Data
Jul. 27, 2010 (TW) 099124643

(51) Int. Cl. H01L 31/0216; H01L 31/18; C23C 14/35

(52) U.S. Cl. 136/256; 204/192.25; 438/95; 257/E31.004

(57) ABSTRACT

A thin film solar cell structure and the fabricating method thereof are disclosed. A passivation layer is embedded into the thin film solar cell structure to be in contact with an absorbing layer. The interface trap density of the absorbing layer is reduced by the surface electric field of the passivation layer. The invention helps improve the power conversion efficiency and protect the absorbing layer.

### BACKGROUND OF THE INVENTION

1. Field of Invention

The invention relates to a solar cell structure and the fabricating method thereof. In particular, the invention relates to a thin-film solar cell structure that uses a chemical thin film as its absorbing layer and the fabricating method thereof.

2. Related Art

In recent years, the solar energy industry gradually turns its research emphasis from conventional wafer manufacturing to thin films. Compound thin films, in particular, receive particular attention. Compound thin film solar cells compared with wafer solar cells have many advantages, such as higher conversion efficiency, lower cost, wider absorbing range, more flexible, and possible for large area applications. Among various chemical compounds, copper indium gallium selenium (CIGS) materials have a wide absorbing spectrum. They can absorb more solar power to increase the conversion efficiency.

Please refer to FIG. 1 for a cross-sectional view of the structure of a conventional compound thin film solar cell. This compound thin film solar cell 10 includes: a substrate 11, a metal layer 12, an absorbing layer 13, a buffer layer 14, and a window layer 15. Generally speaking, the most bottom substrate 11 is glass or some flexible material, such as aluminum alloy foil and copper foil. The substrate 11 is then sputtered with Mo to form the metal layer 12 as a back electrode layer. After the metal layer 12 forms, a compound such as CIGS is sputtered onto the metal layer 12 to form the absorbing layer 13. Afterwards, CdS is deposited on the absorbing layer 13 by chemical bath deposition to form the buffer layer 14. ZnO is grown on the buffer layer 14 by sputtering to form the window layer 15. However, after the absorbing layer 13 is cut by a machine or laser, many interface trap densities form on the absorbing layer 13. They even result in interface binding and greatly lower the power conversion efficiency.

In summary, the prior art always has the problem that the power conversion efficiency is affected by the interface trap density. Therefore, it is desirable to provide a better solution.

### SUMMARY OF THE INVENTION

In view of the foregoing, the specification discloses a thin film solar cell structure and the fabricating method thereof.

One embodiment of the disclosed thin film solar cell structure includes: a substrate, a metal layer, an absorbing layer, and a passivation layer. The metal layer is formed on the substrate. The absorbing layer is formed on the metal layer. The passivation layer is formed on the absorbing layer. The surface electric field of the passivation layer passivates the absorbing layer.

Another embodiment of the disclosed thin film solar cell structure also includes: a substrate, a metal layer, an absorbing layer, and a passivation layer. The metal layer is formed on the substrate. The absorbing layer is formed on the metal layer. The passivation layer is formed on the metal layer and contacts at least one side of the absorbing layer. The surface electric field of the passivation layer passivates the absorbing layer.

The disclosed fabricating method of thin film solar cells includes the steps of: providing a substrate; forming a metal layer on the substrate; forming an absorbing layer on the metal layer; and forming a passivation layer on the absorbing layer, with the surface electric field of the passivation layer passivating the absorbing layer.

The disclosed structure and fabricating method differ from the prior art in the following. By embedding the passivation layer in the thin film solar cell, the passivation layer is in contact with the absorbing layer. The surface electric field of the passivation layer thus reduces the interface trap density of the absorbing layer.

The invention achieves the goal of increasing power conversion efficiency and protecting the absorbing layer.

### BRIEF DESCRIPTION OF THE DRAWINGS

The invention will become more fully understood from the detailed description given herein below illustration only, and thus is not limitative of the present invention, and wherein:

FIG. 1 is a cross-sectional view of the structure of a conventional thin film solar cell;

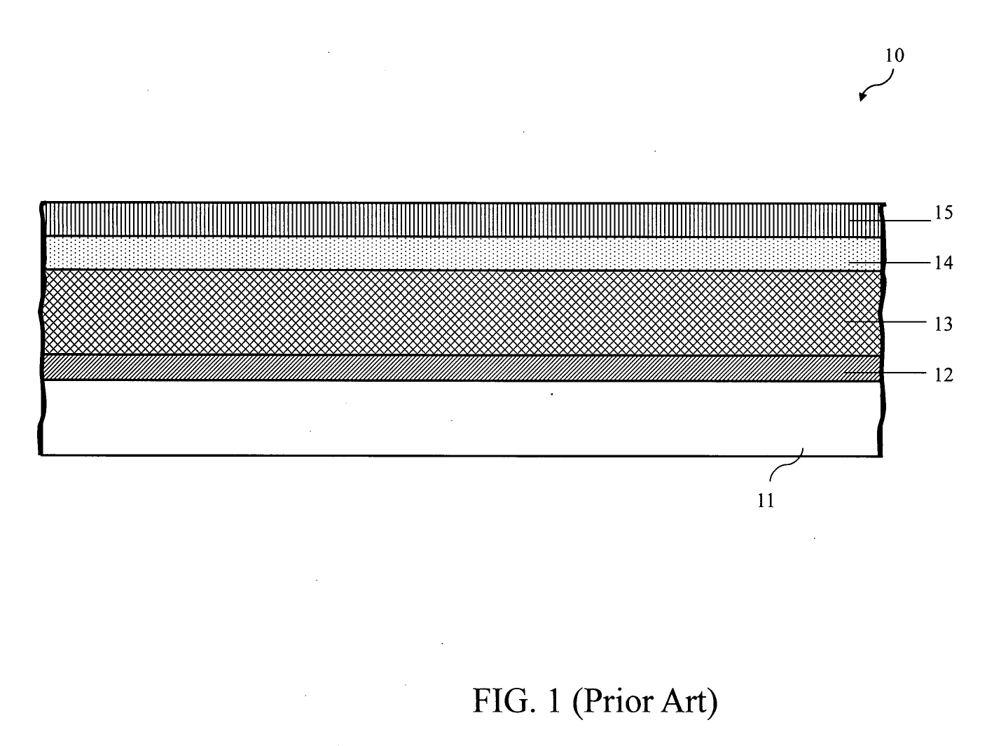

FIG. 2 is a cross-sectional view of a first structure of the disclosed thin film solar cell;

FIG. 3 is a flowchart of the disclosed fabricating method of a thin film solar cell;

FIG. 4 is a cross-sectional view of a second structure of the disclosed thin film solar cell;

FIG. 5 is a cross-sectional view of a third structure of the disclosed thin film solar cell; and

FIG. 6 is a cross-sectional view of a fourth structure of the disclosed thin film solar cell.

### DETAILED DESCRIPTION OF THE INVENTION

The present invention will be apparent from the following detailed description, which proceeds with reference to the accompanying drawings, wherein the same references relate to the same elements.

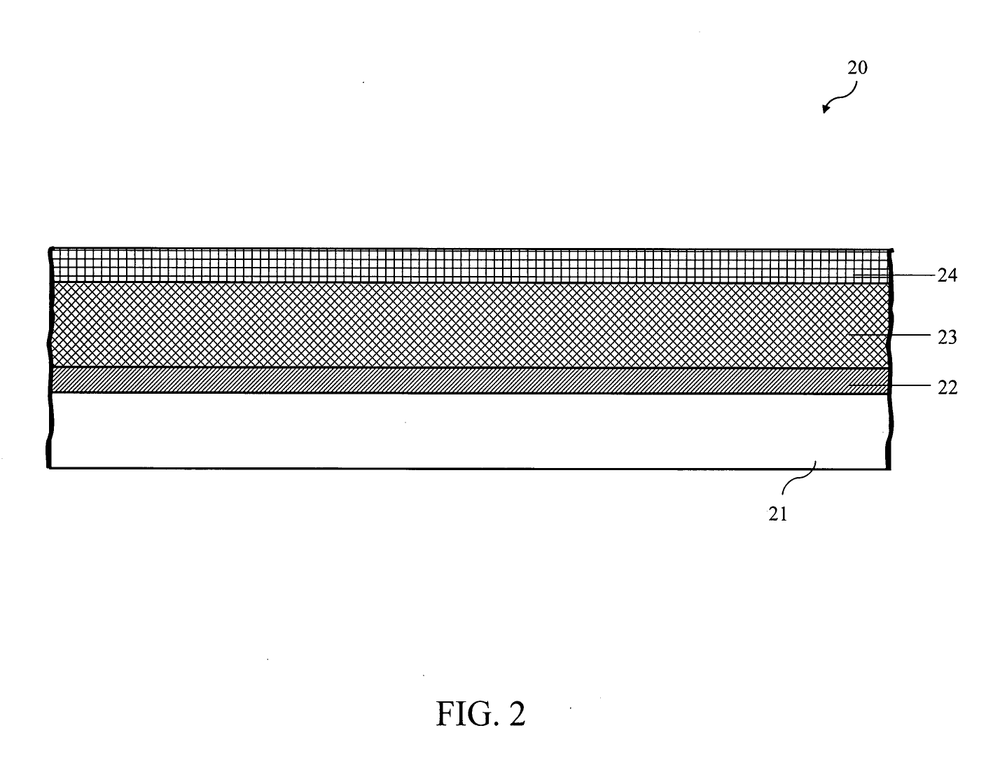

We first describe the structure of the disclosed thin film solar cell. FIG. 2 is a cross-sectional view of the first structure of thin film solar cell according to the invention. The thin film solar cell 20 includes: a substrate 21, a metal layer 22, an absorbing layer 23, and a passivation layer 24. The substrate 21 is made of a flexible material (also called soft material), glass, or polyimide (PI). In practice, the flexible material can be aluminum alloy foil, copper foil, and so on. Besides, the substrate 21 has to be first washed before subsequent sputtering and deposition.

The metal layer 22 forms on the substrate 21. In practice, the metal layer 22 is grown on the substrate 21 by sputtering Mo onto the substrate 21, and is used as a back electrode layer for conducting electricity. In addition, the metal layer 22 can also be formed by depositing a layer of Mo using electron-beam evaporation (EBE) and connected to the positive electrode.

The absorbing layer 23 forms on the metal layer 22. The material of the absorbing layer 23 is such compound as copper indium gallium selenium (CIGS), copper indium selenium (CIS), or copper gallium selenium (CGS). The absorbing layer 23 can be formed on the metal layer 22 by co-evaporation, sputtering, or printing. The absorbing layer 23 is P-type. In practice, the CIGS thin film can be formed using the vacuum process of four-element co-evaporation or the combination of sputtering and selenium. In particular, co-evaporation can freely control the composition and energy gap of the thin film in order to make high-efficiency thin film solar cells. However, it is harder to control and more difficult in producing large-area products. For the combination of sputtering and selenium, one has to be careful in processing special gas (e.g., HSe).

Since CIS can form a thin film between 350° C. to 550° C. Therefore, when using CIS as the absorbing layer 23, one can use the cheaper soda-lime glass as the substrate 21.

The passivation layer 24 forms on the absorbing layer 23. The passivation layer 24 carries sufficient positive or negative fixed charges to form a surface electric field in order to passivate the absorbing layer 23. The passivation refers to the action of filling defects in the absorbing layer 23. For example, the absorbing layer 23 after laser cutting produces an interface trap density that affects power conversion efficiency. In practice, the passivation layer 24 can be grown from Al₂O₃ by atomic layer deposition (ALD), low pressure chemical vapor deposition (LPCVD), sputtering, or sol-gel. The growth thickness is pervious to light (e.g., the growth thickness can between 30 nm and 100 nm). As a result, the negative fixed charges on Al₂O₃ produces a surface electric field so that there is less surface binding on the absorbing layer 23, rendering a better passivation effect. It should be noted that the invention is not restricted to the above-mentioned thickness of the passivation layer 24. Moreover, Al₂O₃ can enclose the absorbing layer 23 or even grow on the metal layer 22, in contact with at least one side of the absorbing layer 23. The details will be described later. Besides, the passivation layer 24 prevents moisture and oxygen from directly contacting the absorbing layer. The absorbing layer 23 is thus free from deterioration in power conversion efficiency due to moisture and oxygen.

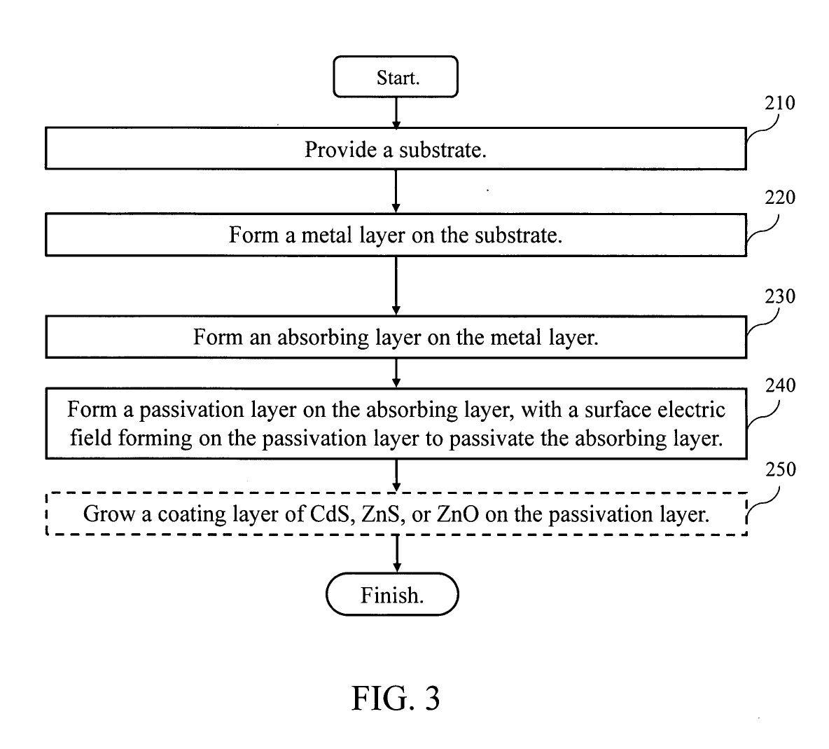

FIG. 3 is a flowchart of the disclosed fabricating method of a thin film solar cell. The method includes the steps of: providing a substrate 21 (step 210); forming a metal layer 22 on the substrate 21 (step 220); forming an absorbing layer 23 on the metal layer 22 (step 230); and forming a passivation layer 24 on the absorbing layer 23, with the surface electric field of the passivation layer 24 passivating the absorbing layer 23 (step 240). The above-mentioned steps embed the passivation layer 24 in the thin film solar cell 20 so that the passivation layer 24 is in contact with the absorbing layer 23. The surface electric field of the passivation layer 24 reduces the interface trap density of the absorbing layer 23.

Besides, step 240 can be further followed by the step of growing a coating layer of CdS, ZnS, or ZnO on the passivation layer 24 (step 250). The coating layer and the passivation layer 24 are both N-type in order to form a P—N junction with the P-type absorbing layer 23. In practice, since CdS contains poisonous cadmium, one can use ZnS instead.

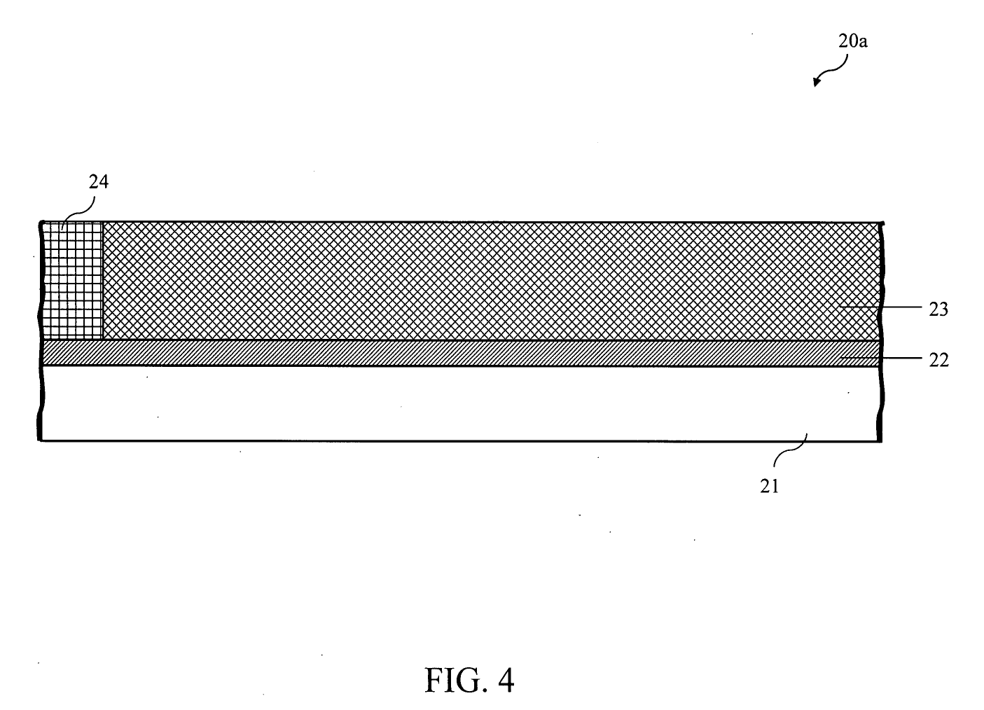

Please refer to FIG. 4 for a cross-sectional view of the second structure of a thin film solar cell according to the invention. In addition to the structure of the thin film solar cell 20, Al₂O₃ can grow on the metal layer 22 to form the passivation layer 24 in practice. The passivation layer 24 touches at least one side of the absorbing layer 23. Practically, the finished passivation layer 24 is as shown in FIG. 4. The metal layer 22 of the thin film solar cell 20a is simultaneously grown with the absorbing layer 23 and the passivation layer 24. After laser cutting the cutting surface of the absorbing layer 23 has an interface trap density. As shown in FIG. 4, the passivation layer 24 grown on the cutting surface of the absorbing layer 23 of the thin film solar cell 20a produces a surface electric field due to the negative fixed charges of Al₂O₃. The interface trap density of the cutting surface of the absorbing layer 23 is thus reduced. The surface binding is reduced to achieve good passivation.

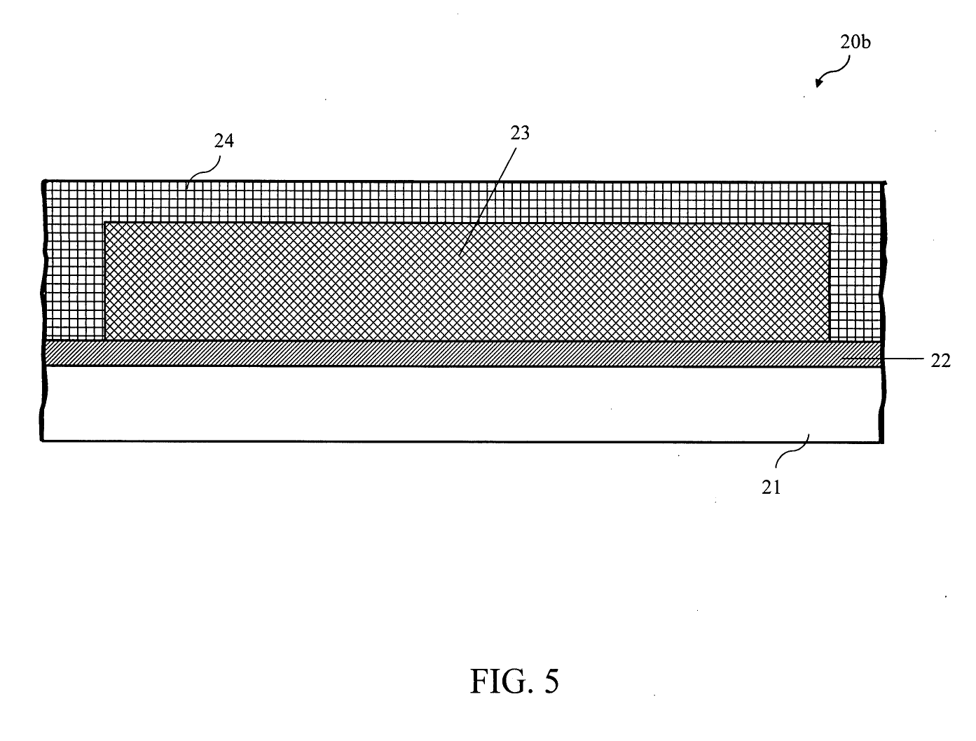

FIG. 5 is a cross-sectional view of the third structure of a thin film solar cell according to the invention. In practice, Al₂O₃ is grown on the absorbing layer 23 by ALD, LPCVD, sputtering, or sol-gel. Its structure can be the passivation layer 24 that encloses the absorbing layer 23, as shown in the drawing. Therefore, the passivation layer 24 of the thin film solar cell 20b can effectively prevent the absorbing layer 23 cut by a machine or laser from directly contacting moisture and oxygen. In other words, in addition to using the negative fixed charges of the aluminum oxide to form a surface electric field to passivate the absorbing layer 23, the passivation layer 24 further prevents moisture and oxygen from contacting the absorbing layer 23. Thus, the material of the absorbing layer 23 would not deteriorate to affect the power conversion rate.

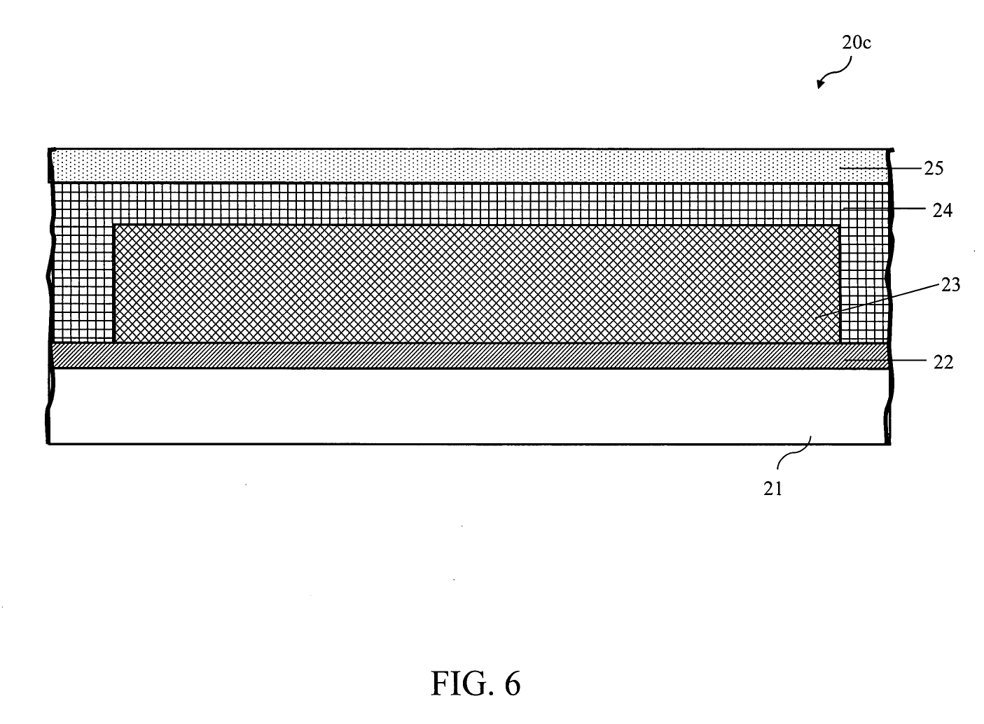

Please refer to FIG. 6 for a cross-sectional view of the fourth structure of a thin film solar cell according to the invention. As mentioned before, aluminum oxide can be the passivation layer enclosing the absorbing layer 23 as shown in FIG. 5. In practice, it is possible to grow a coating layer of CdS, ZnS, or ZnO on the passivation layer 24, as shown in FIG. 6. For example, suppose the coating layer 25 is CdS or ZnS. The coating layer 25 can then serve as the buffer layer of the thin film solar cell 20c. If the coating layer 25 is ZnO, then it can be the window layer of the thin film solar cell 20c.

In summary, the invention differs from the prior art in that a passivation layer 24 is embedded in the thin film solar cell 20 to be in contact with the absorbing layer 23. The surface electric field of the passivation layer 24 reduces the interface trap density of the absorbing layer 23. This disclosed technique solves problems existing in the prior art and increase the power conversion efficiency as well as protect the absorbing layer.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A structure of a thin film solar cell, comprising:
a substrate;
a metal layer formed on the substrate;
an absorbing layer formed on the metal layer; and
a passivation layer formed on the absorbing layer and producing a surface electric field to passivate the absorbing layer.

2. The structure of a thin film solar cell according to claim 1, wherein the substrate is a flexible material, glass, or polyimide (PI).

3. The structure of a thin film solar cell according to claim 1, wherein the metal layer is grown on the substrate by sputtering Mo thereon.

4. The structure of a thin film solar cell according to claim 1, wherein the material of the absorbing layer is copper indium gallium selenium (CIGS), copper indium selenium (CIS), or copper gallium selenium (CGS) that is grown on the metal layer by co-evaporation, sputtering, or printing.

5. The structure of a thin film solar cell according to claim 1, wherein the passivation layer is a aluminum oxide that is grown using the method of atomic layer deposition (ALD), low pressure chemical vapor deposition (LPCVD), sputtering, or sol-gel and has negative fixed charges.

6. The structure of a thin film solar cell according to claim 5, wherein the thickness of the aluminum oxide is pervious to light.

7. The structure of a thin film solar cell according to claim 5, wherein the aluminum oxide grows on the absorbing layer and encloses the absorbing layer.

8. A structure of a thin film solar cell, comprising:
a substrate;
a metal layer formed on the substrate;
an absorbing layer formed on the metal layer; and
a passivation layer formed on the metal layer and in contact with at least one side of the absorbing layer, and producing a surface electric field to passivate the absorbing layer.

9. The structure of a thin film solar cell according to claim 8, wherein the substrate is a flexible material, glass, or polyimide (PI).

10. The structure of a thin film solar cell according to claim 8, wherein the metal layer is grown on the substrate by sputtering Mo thereon.

11. The structure of a thin film solar cell according to claim 8, wherein the material of the absorbing layer is CIGS, CIS, or CGS that is grown on the metal layer by co-evaporation, sputtering, or printing.

12. The structure of a thin film solar cell according to claim 8, wherein the passivation layer is a aluminum oxide that is grown using the method of ALD, LPCVD, sputtering, or sol-gel and has negative fixed charges.

13. A fabricating method of a thin film solar cell, comprising the steps of:
providing a substrate;
forming a metal layer on the substrate;
forming an absorbing layer on the metal layer; and
forming a passivation layer on the absorbing layer, the passivation layer producing a surface electric field to passivate the absorbing layer.

14. The method of claim 13, wherein the substrate is a flexible material, glass, or PI.

15. The method of claim 13, wherein the metal layer is grown on the substrate by sputtering Mo thereon.

16. The method of claim 13, wherein the material of the absorbing layer is CIGS, CIS, or CGS that is grown on the metal layer by co-evaporation, sputtering, or printing.

17. The method of claim 13, wherein the passivation layer is a aluminum oxide that is grown using the method of ALD, LPCVD, sputtering, or sol-gel and has negative fixed charges.

18. The method of claim 17, wherein the thickness of the aluminum oxide is pervious to light.

19. The method of claim 17, wherein the aluminum oxide grows on the absorbing layer and encloses the absorbing layer.

20. The method of claim 13 further comprising the step of growing a coating layer of CdS, ZnS, or ZnO on the passivation layer.
